(19) United States
(12) Patent Application Publication
(10) Pub. No.: US 2025/0336812 A1
(43) Pub. Date: Oct. 30, 2025

(54) THIN FILM RESISTOR INTEGRATION WITHIN A COPPER INTERCONNECT

(71) Applicant: TEXAS INSTRUMENTS INCORPORATED, Dallas, TX (US)

(72) Inventors: Hongmei Li, Allen, TX (US); Qi-Zhong Hong, Richardson, TX (US); Gregory Boyd Shinn, Dallas, TX (US)

(21) Appl. No.: 18/649,170

(22) Filed: Apr. 29, 2024

(51) Int. Cl. H01L 23/522; H01L 21/768; H01L 23/528; H01L 23/532; H01L 27/08

(52) U.S. Cl. CPC H01L 23/5228; H01L 21/76843; H01L 23/5226; H01L 23/53228; H01L 23/53266; H10D 84/209; H01L 23/5283

(57) ABSTRACT

An integrated circuit (IC) including a TFR is disclosed. In one example, the IC comprises a dielectric layer over a semiconductor substrate, a resistive layer over the dielectric layer, a metal interconnect trace over a header end of the resistive layer, a via extending from the metallic interconnect trace toward the resistive layer, and a metallic barrier layer between the via and the resistive layer.

### FIELD OF THE DISCLOSURE

Disclosed implementations relate generally to the field of integrated circuits (ICs) and IC fabrication. More particularly, but not exclusively, the disclosed implementations relate to thin film resistor (TFR) integration.

### BACKGROUND

Metal thin film resistors (TFRs) may be formed using a variety of resistive metals. Nichrome (NiCr) and sichrome (SiCr) are two that are commonly used. These types of TFRs are formed in the backend of line (BEOL) of an integrated circuit manufacturing flow. BEOL resistors have less parasitic capacitance than resistors formed in the frontend of line (FEOL) that typically use polysilicon, silicide, or nwell formed in or over the semiconductor substrate because BEOL resistors are formed at a greater distance from the semiconductor substrate.

Integrating a metal TFR in the BEOL of an integrated circuit manufacturing flow adds cost and cycle time. As the advances in the design of interconnects formed in BEOL continue to take place, improvements in microelectronic devices, including metal TFRs and their integration, are also being concomitantly pursued.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to an IC (also referred to as an electronic device, IC device, semiconductor device, etc.) including one or more TFRs integrated within a BEOL copper interconnect flow. In one example, an IC is disclosed, which may comprise, among others, a dielectric layer over a semiconductor substrate; a resistive layer over the dielectric layer; a metal interconnect trace over a header end of the resistive layer; a via extending from the metallic interconnect trace toward the resistive layer; and a metallic barrier layer between the via and the resistive layer. In some arrangements, the metallic barrier layer may be disposed in contact with the via and the resistive layer.

In one example, a method of fabricating an IC device including a TFR is disclosed. The method may comprise, among others, forming a resistive layer over a semiconductor substrate; forming a first dielectric layer over the resistive layer; forming a metallic barrier layer contacting the resistive layer through an opening in the first dielectric layer; and forming a conductive via that extends to the metallic barrier layer through a second dielectric layer over the resistive layer, wherein the metallic barrier layer may be disposed in contact with the via and the resistive layer.

In one example, a method of fabricating an IC device including a TFR is disclosed. The method may comprise, among others, forming a first dielectric layer over a semiconductor substrate; forming a resistive layer over the first dielectric layer; forming a second dielectric layer over the resistive layer; patterning the second dielectric layer to form header trenches over header regions of the resistive layer, a remaining portion of the second dielectric layer covering a resistor body spanning between the header regions of the resistive layer; forming a metallic barrier layer in the header trenches; depositing an inter-level dielectric (ILD) layer over the header trenches and the remaining portion of the second dielectric layer; forming vias in or through the ILD layer, the vias each landing on the metal barrier layer in respective header trenches; and forming metal interconnect traces over and in electrical contact with the vias, the metal interconnect traces and the vias surrounded by a same barrier material as the metallic barrier layer.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure described in the following Detailed Description taken in connection with the appended claims and with reference to the attached drawing Figures in which:

FIGS. 1A to 1J illustrate sectional views of a semiconductor device at progressive stages of fabrication where a thin film resistor may be integrated according to some examples of the present disclosure; and

FIGS. 2 and 3 are flowcharts relating to IC fabrication methods according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of thin film resistor (TFR) integration within a BEOL copper interconnect flow.

Thin film resistors (TFRs) may offer low temperature coefficient of resistance (TCR) and have many applications. For example, high precision analog circuits (e.g., voltage references, digital-to-analog and analog-to-digital converters (DACs/ADCs), biosensing analog frontends (AFEs), etc.) may include one or more TFRs because of the low TCR. In some baseline processes, a TFR may be formed between a metallization layer and an adjacent metallization layer formed in the BEOL processing of a semiconductor device. Such inter-level metal integration of TFRs requires the formation of TFR head structures where vias can land and make contact with the TFR film. As interconnect technologies continue to advance, e.g., including damascene copper metallization, it becomes important that the TFR films are protected against copper diffusion/migration that may be caused in the head structures, which can compromise the resistivity characteristics of the TFR.

Examples of the present disclosure advantageously provide TFR arrangements where the head structures (also referred to as header ends or header structures) of a TFR are provided with a metallic barrier layer configured to mitigate the deleterious effects of copper diffusion, which may be caused or exacerbated in a range of temperatures that may be encountered in a process flow. Further, the examples herein provide header barrier layers comprising materials that may also be used for forming barrier layers associated with copper vias used for accessing the TFRs and/or interconnecting metal layers at different levels of a multilevel interconnect scheme. Some examples herein may therefore be configured to enhance the reliability of TFR devices integrated within in a copper interconnect scheme while facilitating process flow integration with minimal impact. Additionally, example TFR structures may be provided with reduced thickness relative to baseline TFR structures because of the integration scheme set forth herein. Whereas the examples may provide materials and processes that advantageously allow TFR integration in a variety of interconnect schemes involving copper, no particular result is a requirement unless explicitly recited in a particular claim.

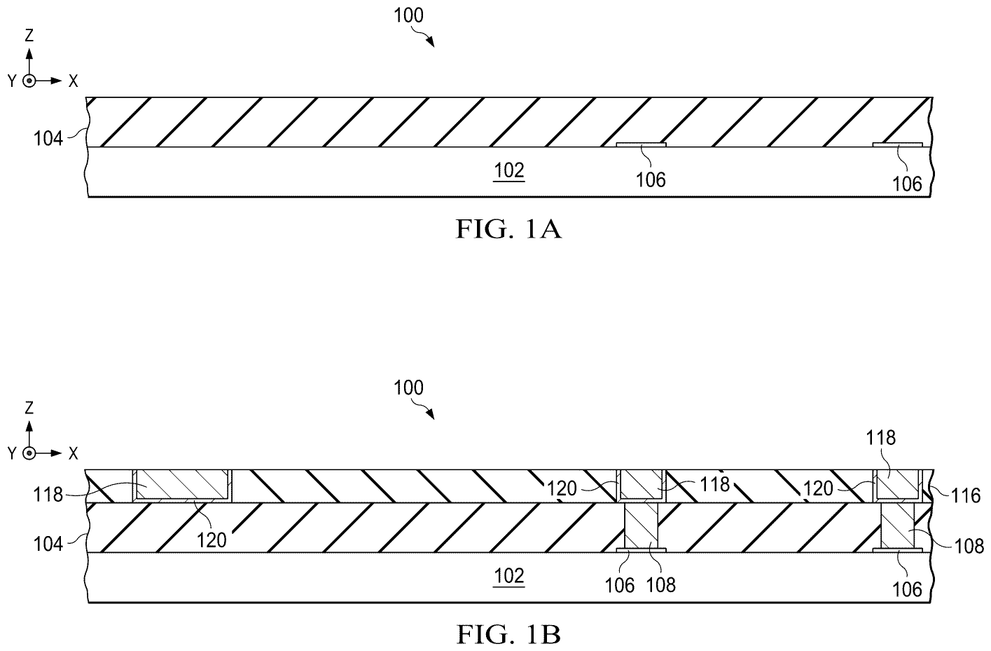

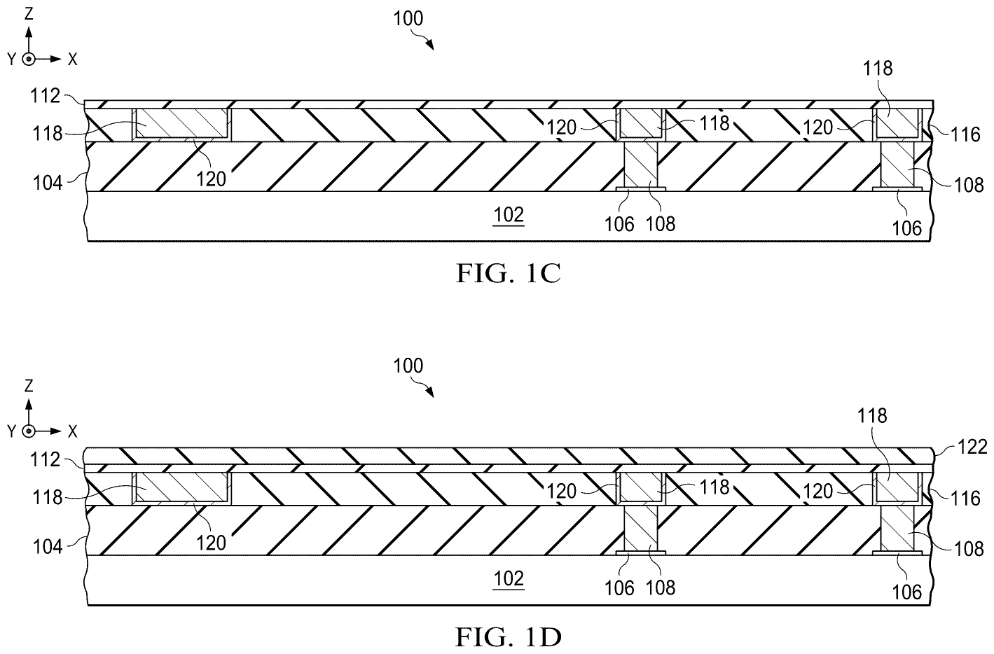

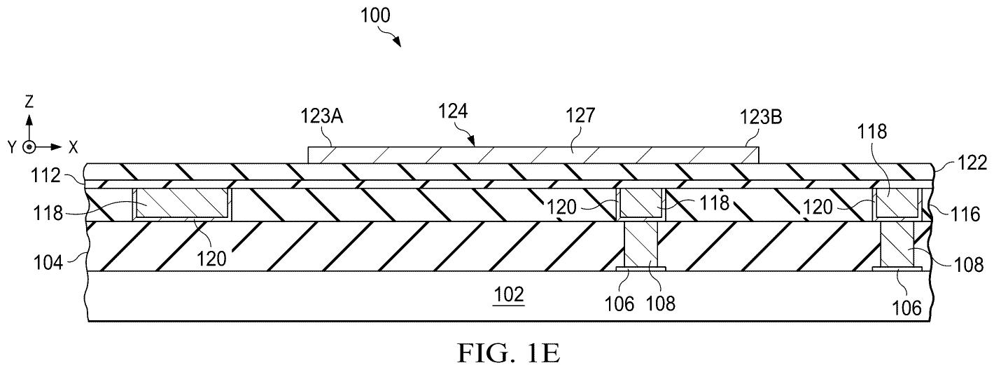

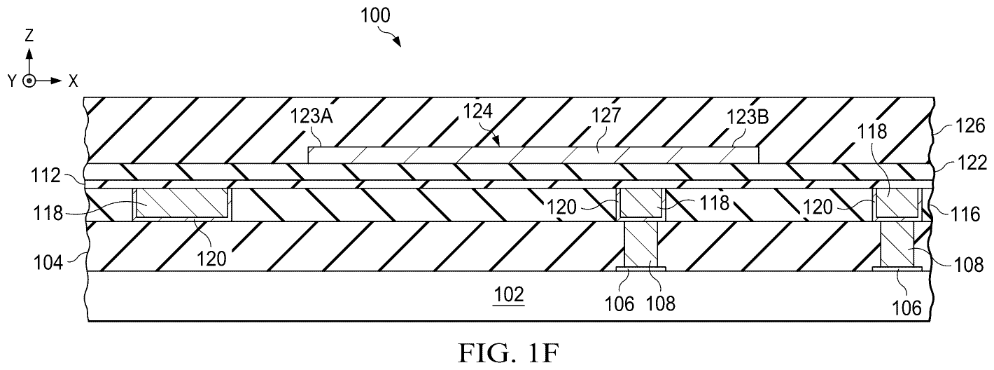

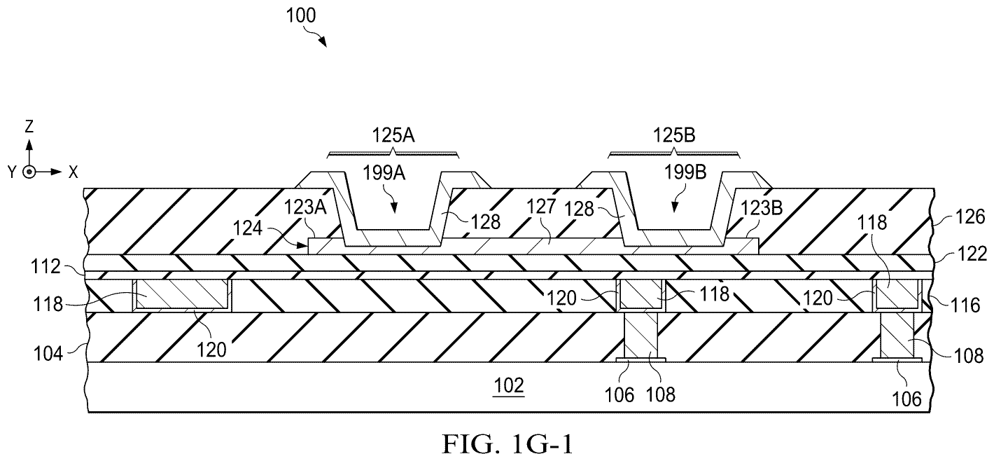

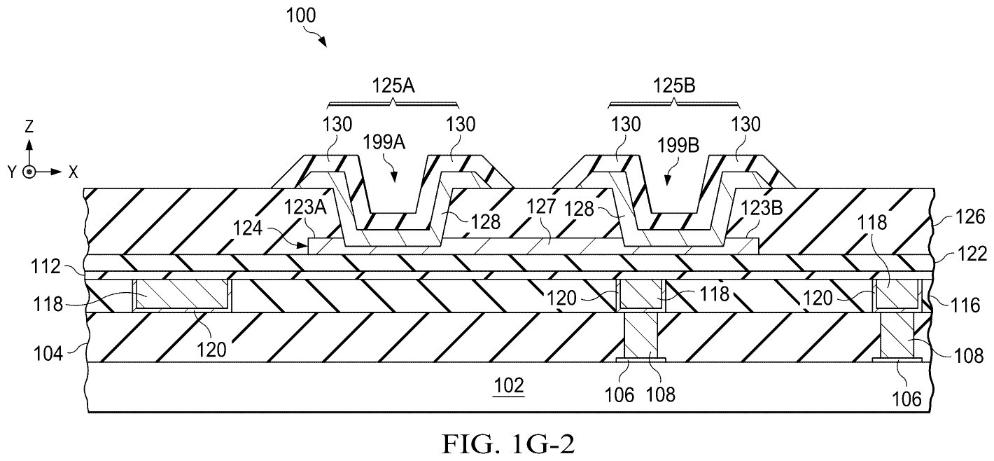

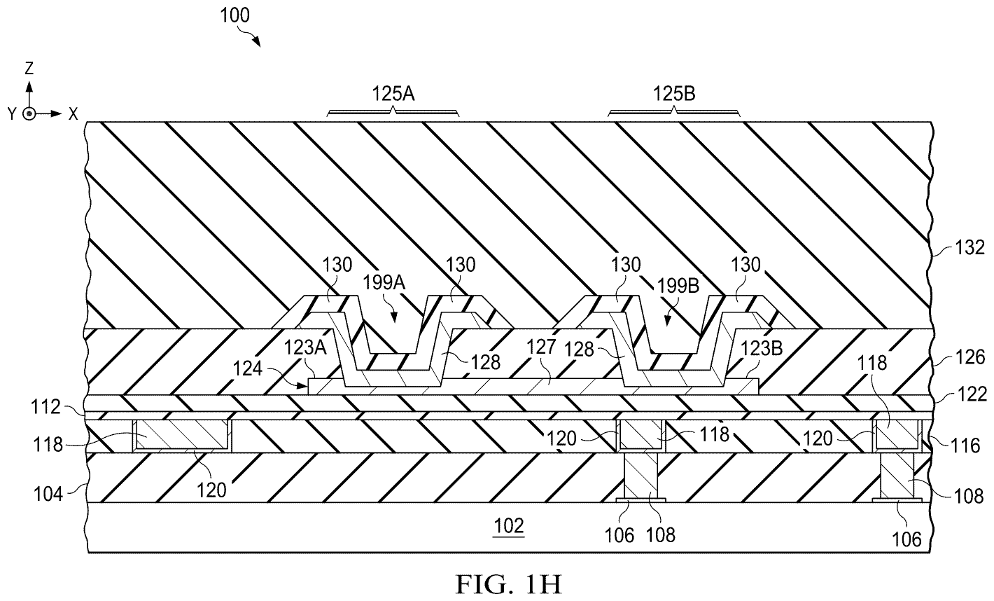

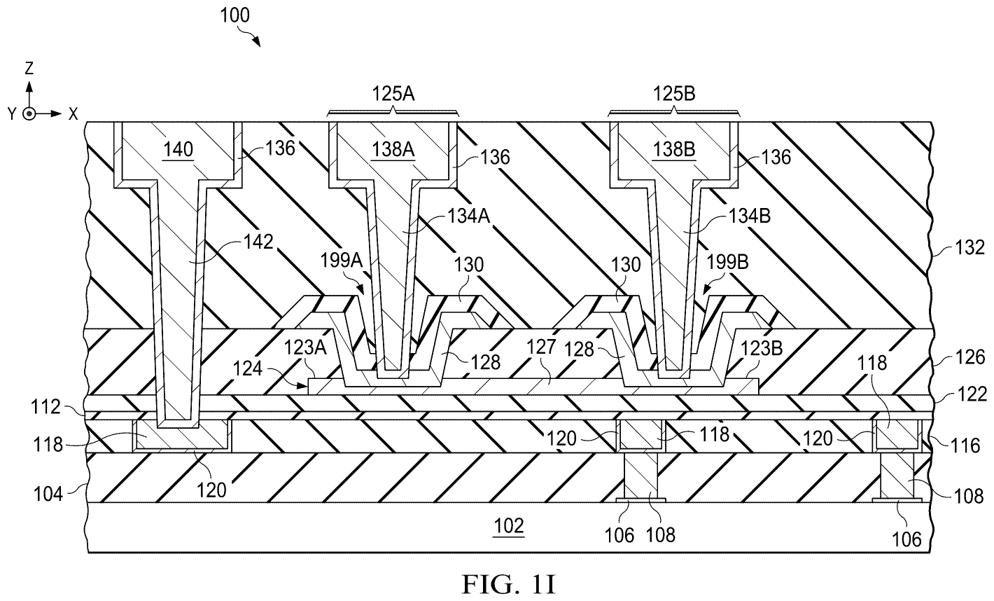

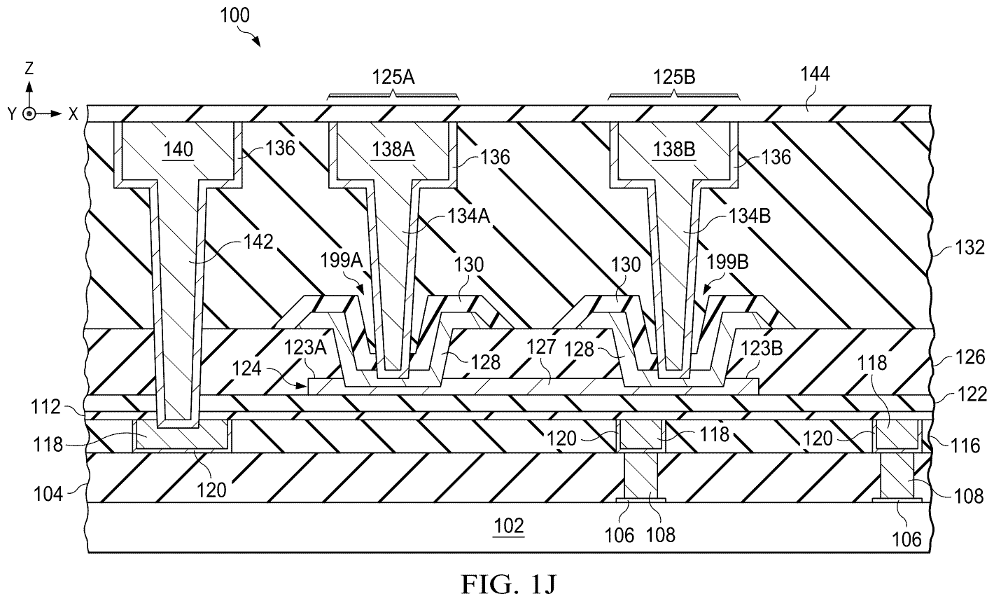

FIGS. 1A-1J illustrate sectional views of a semiconductor device 100, e.g., an IC or a discrete device, at progressive stages of fabrication where one or more TFRs may be integrated in a BEOL copper interconnect flow according to some examples of the present disclosure. In one arrangement, a resistive film or layer operable as a TFR structure having header ends (or “heads”) may be integrated between two metal layers provided at different levels of a multilevel interconnect scheme, where the header ends may each include a metallic barrier layer comprising a same barrier material as do the copper vias provided for facilitating connectivity to the respective header ends. In some variations, the header ends may also include respective dielectric diffusion barriers over the metallic barrier layers as an optional implementation. In yet another arrangement, a subset of the illustrated process stages may be repeated successively in an iterative process loop to obtain a TFR arrangement where multiple TFRs integrated at different levels of the multilevel interconnect may be provided as part of the semiconductor device 100.

For the sake of clarity, the illustrated sectional views do not show the details of microelectronic devices and components, e.g., transistors, isolation regions, laterally diffused extensions, N-wells, P-wells, deep wells, shallow wells, etc., formed in or over a semiconductor substrate 102 of the semiconductor device 100 as part of a FEOL fabrication flow. In representative examples, the transistors may include nMOS or pMOS transistors, junction field effect transistors (JFETs), NPN or PNP bipolar transistors, biCMOS transistors, Group III-Nitride devices, or combinations thereof. Depending on application, the semiconductor device 100 may be representative of a device including analog, digital and/or mixed signal circuitry that may be fabricated using any type or combination of fabrication technologies and/or technology nodes. For example, the semiconductor device 100 may be a device where different technologies suitable for respective types of product design may be integrated within the same chip or IC device, e.g., linear BiCMOS or LBC (a bipolar-CMOS combination technology where MOS and bipolar technology may be used for analog functions and CMOS may be used for digital logic design), BCD (a bipolar-CMOS-DMOS combination technology where DMOS may be integrated within the IC device for power and high-voltage portions that also has analog and digital portions), and the like. In some examples, the semiconductor device 100 may be representative of an ADC/DAC converter, where a TFR may be provided as part of a resistive ladder network, without limitation.

FIG. 1A depicts a cross-sectional view of the semiconductor device 100 at a pre-metallization stage, e.g., after forming various circuit elements over or in the semiconductor substrate 102 in a FEOL flow. The semiconductor substrate 102 may predominantly comprise suitably doped silicon as substate material in some examples, although other semiconductor materials such as silicon-on-insulator, Ge, SiGe, GaAs, SiC, GaN, other Group III-V materials, etc., may be used in some implementations, where one or more epitaxial layers or single-crystal layers may be formed or provided as part of the semiconductor substrate 102. Further, the cross-sectional view of FIG. 1A also depicts one or more polysilicon interconnects or traces 106 formed between the semiconductor substrate 102 and a pre-metal dielectric (PMD) layer 104 formed over the semiconductor substrate 102, where the polysilicon traces 106 may be utilized for facilitating connectivity with respect to structures formed in a BEOL flow as an optional implementation. In some arrangements, therefore, the polysilicon traces 106 may be omitted. Where provided, the polysilicon interconnects 106 may have a suitable thickness and may be silicided appropriately (not specifically shown in the Figures) where metallic contacts are to be formed through the PMD layer 104. An example silicidation loop for use with the polysilicon interconnects 106 may comprise deposition of a metal (e.g., nickel (Ni), cobalt (Co), titanium (Ti), tungsten (W), molybdenum (Mo), platinum (Pt), palladium (Pd), tantalum (Ta), etc., without limitation), annealing to form silicide (e.g., using heat, ionic energy, laser energy, etc.), followed by the removal of unreacted metal and further annealing to a form low resistivity phase of the silicide material. Although not specifically shown in the Figures, the PMD layer 104 may include one or more layers and/or sublayers formed of different materials, e.g., doped dielectric material such as phosphorous-doped silicate glass (PSG), silicon nitride (SiN) or silicon dioxide (SiO₂), etc., that may be planarized (e.g., by chemical mechanical polishing (CMP) and/or etchback) to a total thickness of about 0.3 microns (μm) to 2 μm or more. In some examples, the PMD layer 104 may be formed by plasma enhanced chemical vapor deposition (PECVD) and/or by a high density plasma (HDP) deposition.

FIG. 1B depicts a stage of the semiconductor device 100 where metallic contacts 108 are formed in the PMD layer 104 using a contact pattern and etch process, where the contacts 108 may be configured to land on silicided polysilicon interconnects 106. Depending on implementation with respect to pre-BEOL metallization, contact formation in the PMD layer 104 may include one or more process loops where different contacts 108 may be formed based on the required connectivity with respect to any upper level metal structures that may be formed as part of a multilevel interconnect scheme associated with the semiconductor device 100. Further, the contacts 108 may have different form factors, e.g., having circular, square or rectangular cross-sections with variable heights.

Without limitation, some examples of contact formation are set forth herein. In some implementations, contacts may include an adhesion liner of titanium formed by a sputter process. In some implementations, contacts may include a barrier liner of titanium nitride (TiN) or tantalum nitride (TaN) on the adhesion liner, e.g., where copper is used for contact formation. Example barrier liners may be formed by a reactive sputter process, an atomic layer deposition (ALD) process, etc., and may include a variety of metallic/oxide/nitride compositions. In some implementations, contacts may include a fill plug of tungsten on the barrier liner, formed by a metal organic chemical vapor deposition (MOCVD) process including reduction of tungsten hexafluoride. In some implementations, any overburden of the fill plug metal, barrier liner and adhesion liner on a top surface of the PMD layer 104 may be removed by a CMP process, an etchback process, or a combination of both.

In the representative example of FIG. 1B, the contacts 108 may comprise tungsten plugs having a thickness (e.g., width, diameter or a similar horizontal dimension along the X-axis) around 0.02 μm to 0.4 μm and a height of about 0.3 μm to 2 μm depending on implementation and consistent with the PMD layer 104. FIG. 1B also illustrates the formation of a dielectric layer 116 having a suitable thickness, e.g., about 80 nm to 500 nm, that may be formed over the PMD layer 104. In some examples, the dielectric layer 116 may be operable as an intra- or inter-metal dielectric (IMD) layer comprising one or more sublayers and may include SiO₂, undoped or doped silicate glass, spin-on-glass, fluorosilicate glass or other low-k dielectric constant material (e.g., a dielectric constant of less than about 4), which may be deposited using suitable baseline procedures. In some examples, the dielectric layer 116 may be planarized, e.g., with CMP and/or etchback. FIG. 1B further illustrates the stage where one or more metal interconnect structures 118 are formed in the dielectric layer 116. In some examples, the metal interconnect structures 118 may be formed as part of fabricating a first metal layer, e.g., comprising copper, that may be provided as a first metallization level of a multilevel interconnect arrangement of the semiconductor device 100. In some examples, the first metal layer may be labeled MET1, MT1, or M1, or with terms of similar import. Where the metal interconnect structures 118 are fabricated as part of an upper metallization level for purposes of some examples, they may be referred to as MET2 interconnect structures, MET3 interconnect structures, and the like. In such arrangements, there may be one or more inter-level dielectric (ILD) layers and/or associated IMDs provided between the PMD layer 104 and the dielectric layer 116. Regardless of the metallization level of the interconnect structures 118, they may be fabricated in a copper damascene process, where the interconnect structures 118 may be surrounded by a suitable barrier layer 120 to enhance the ohmic contact and adhesion of the interconnect structures 118 as well as function as a barrier against copper diffusion or migration into the surrounding dielectric materials at high temperatures that may be encountered during subsequent processing. In some arrangements, the barrier layer 120 may have a thickness of about 2 nm. Example diffusion/migration barrier materials may comprise transition metals such as Ta, W and Ti as well as their compositions with nitrogen (N), carbon (C), and/or silicon (Si), resulting in refractory compounds including Ta/TaN, W₂N, TIN, TIC, TaSiN, Si₃N₄, and the like. Additional and/or alternative examples herein may include barrier materials comprising platinum group metals (PGMs) such as ruthenium (Ru)-based materials, self-assembled molecular layers (SAMs) and high-entropy alloys (HEAs).

FIG. 1C depicts a stage where an etch stop layer 112 is formed over the dielectric layer 116, which may be operable as an IMD layer as noted above. In some examples, the etch stop layer 112 may also function as a dielectric diffusion barrier layer. In some examples, the etch stop layer 112 may have a thickness of about 30 nm to 80 nm and may comprise SiCN, SiC, SiCO, SiON, or Si₃N₄, and the like.

FIG. 1D depicts a stage where a dielectric layer 122 is formed over the etch stop layer 112. The dielectric layer 122 may comprise a variety of dielectric materials including low-k dielectric materials and may have a thickness of about 50 nm to 200 nm. In one implementation, the dielectric layer 122 may comprise a tetra-ethyl-ortho-silicate (TEOS) layer. As will be set forth below, the dielectric layer 122 may be configured as a “liner” for forming a TFR thereon according to some examples herein. In some arrangements, the liner dielectric layer 122 may be referred to as a first dielectric layer for purposes of some examples. As used herein, the terminology of “first dielectric layer”, “second dielectric layer”, etc., may respectively refer to different dielectric layers of a semiconductor device that are formed after a FEOL flow depending on the type and/or metal level of TFR integration implemented, and are not necessarily limited to the dielectric layer 122 shown in FIG. 1D. For example, a first dielectric layer may refer to a dielectric layer formed after the formation of a TFR in some arrangements. In some examples, a second dielectric layer may refer to a dielectric layer formed after the formation of the dielectric layer 122. In some examples, a second dielectric layer may refer to a dielectric layer formed after the formation of a TFR. In yet further examples, terms such as “a first dielectric layer”, “a second dielectric layer”, “a third dielectric layer”, etc., may refer to various ILDs and/or IMDs formed in a BEOL flow depending on the levels of metal layers provided in an interconnect arrangement without necessarily implying or being limited to any specific spatial orientation or hierarchy within the multilevel interconnect arrangement.

FIG. 1E depicts a stage where a resistive layer 124 is formed over the dielectric layer 122. A thin film deposition, pattern and etch process may be used for forming the resistive layer 124, where a first terminal portion 123A and a second terminal portion 123B of the resistive layer 124 may be configured for forming respective header structures thereon as will be set forth below. In versions of the examples herein, the terminal regions 123A/123B may also be referred to as head regions or header regions of the resistive layer 124 where one or more electrical connections are made to the resistive material. The resistive layer 124 may be dimensioned to have a suitable form factor where a resistive body 127 having appropriate resistivity is extended between the terminal portions 123A and 123B. For example, the resistive layer 124 may have a suitable thickness (e.g., around 3 nm to 50 nm or less) and sufficient resistivity (e.g., greater than 100 μΩ-cm), and may comprise a variety of compositions suitable for TFR formation including at least one transitional metal element. In some implementations, the resistive layer 124, also referred to as a TFR layer or simply TFR in some examples, may include a silicon chromium (SiCr) based mixture with an example composition (in relative atomic %) of SiₓCr_{y}C_{z}O_{w}, where x and y can range from 5% to 50%, whereas z and w can range from 0% to 50%. In another implementation, for example, the resistive layer 124 may include a nickel chromium (NiCr) based mixture with an example composition (in relative atomic %) of NiₓCr_{y}C_{z}O_{w}, where x and y can range from 5% to 50%, whereas z and w can range from 0% to 50%. In some examples, desirable resistive materials for forming the resistive layer 124 may include SiCr, NiCr, TaN, SiCCr (silicon carbide-chromium), AlNiCr (aluminum-nickel-chromium), or TiNiCr (titanium-nickel-chromium), without limitation. In general, such resistive materials may be desirable as they have a low TCR (e.g., equal to or less than about 30 ppm/° C.) and because the resistive bodies comprising such materials are capable of having their resistance tuned by various baseline laser trimming processes.

The resistive layer 124 may be formed in various ways depending on the materials used for forming a resistive body of the TFR. Without limitation, physical vapor deposition (PVD) processes such as evaporation or sputtering may be used to deposit the resistive layer 124 in some examples. Depositing the resistive layer 124 may include annealing the layer 124 (e.g., about 400° C. in air for about 30 minutes followed by about 400° C. in a forming gas (e.g., 20% H₂ and a balance of N₂) for about 30 minutes) in some implementations.

In some additional and/or alternative examples, a high-temperature annealing (HTA) process may be implemented in order to increase the resistivity of a TFR such as the resistive layer 124. In some arrangements, annealing temperatures of about 300° C. to 650° C. may be applied over shorter or longer periods of time (e.g., about 30 minutes) to increase the resistivity by or up to three times or more. Higher resistivity is generally desired in a design layout as the size of a TFR may be reduced for given electrical performance requirements, thus saving the chip area of a semiconductor device such as the semiconductor device 100.

FIG. 1F depicts a stage where a dielectric layer 126 is formed over the resistive layer 124. The dielectric layer 126 may comprise a layer having a thickness of about 100 nm to 150 nm, and may comprise any suitable dielectric material, including low-k dielectric materials. In one implementation, the dielectric layer 126 may comprise TEOS. Depending on the examples, the dielectric layer 126 may be referred to as a first dielectric layer or a second dielectric layer for purposes of the present disclosure. The dielectric layer 126 may be patterned and etched to form or define a pair of openings, also referred to as header trenches or apertures, over respective terminal portions 123A and 123B of the resistive layer 124, where the openings may land on or into the resistive terminal portions 123A, 123B. A remaining portion of the dielectric layer 126 (e.g., having a thickness of about 50 nm to 80 nm) may cover the resistive body 127 to provide protection during subsequent processing as will be set forth below. In some arrangements, a TaN barrier layer having a suitable thickness (e.g., about 30 nm to 100 nm) may be formed in each of the header trenches. In the examples herein, TaN is used to form respective TFR header structures so as to function as a diffusion barrier between copper vias to be formed in the header structures and the resistive layer 124. resistor film. Further, because TaN has a lower etch rate compared to TEOS, a via etch process involving forming both TFR vias as well as any inter-level vias may be configured to prevent the TFR vias from penetrating into the terminal portions (e.g., header punch-through), as will be set forth further below. Moreover, TaN may also be used as a diffusion barrier during the formation of the copper vias in some arrangements, thus facilitating a homogeneous interface between the vias and the resistor headers while providing sufficient diffusion barrier capability according to the examples herein.

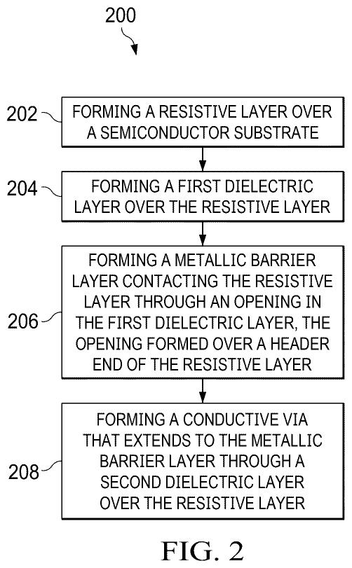

FIG. 1G-1 depicts a stage of the semiconductor device 100 where metallic barrier layers 128 comprising TaN are formed in header apertures 199A and 199B that are formed over respective terminal portions 123A, 123B. In versions of the examples herein, the metallic barrier layer 128 may be fabricated to contact the resistive layer 124 and vias to be formed thereover in the respective header apertures 199A, 199B. Reference numbers 125A and 125B refer to intermediate stages of respective header structures associated with the resistive layer 124. In another variation, dielectric diffusion barrier layers 130 may be optionally formed over the metallic barrier layers 128 as part of the respective header structures 125A and 125B, as illustrated in FIG. 1G-2. Depending on implementation, the dielectric diffusion barrier layers 130 may comprise SiN or a combination of SiN and TEOS, with overall thickness ranging from about 40 nm to 200 nm. Although the subsequent stages of fabrication are directed to the arrangement with the header structures 125A and 125B including the dielectric diffusion barrier layers 130, these stages are equally applicable to the arrangement shown in FIG. 1G-1, with any relevant modifications, where the header structures 125A and 125B do not include the dielectric diffusion barrier layers 130.

FIG. 1H depicts a stage of the semiconductor device 100 where a dielectric layer 132 is formed, which may be planarized (e.g., CMP and/or etchback) to have a thickness of about 400 nm to 600 nm. In some examples, the dielectric layer 132 may be operable as an ILD/IMD layer and may include one or more sublayers comprising SiO₂, undoped or doped silicate glass, spin-on-glass, fluorosilicate glass or other low-k dielectric constant material (e.g., a dielectric constant of less than about 4). In some arrangements, the dielectric layer 132 may be formed using suitable baseline procedures similar to the dielectric layer 116 described above.

FIG. 1I depicts a stage of the semiconductor device 100 where conductive vias 134A, 134B and corresponding metal interconnect structures 138A, 138B are formed in a via pattern and etch process followed by a metal pattern and etch process using appropriate copper damascene processes. As illustrated, metal interconnect traces 138A and 138B may be formed as part of fabrication of a second metal layer, e.g., comprising copper, that may be provided as a second metallization level (e.g., MET2, MT2 or M2, or terms of similar import) of a multilevel interconnect arrangement of the semiconductor device 100. Depending on implementation within the multilevel interconnect arrangement, the metal interconnect structures 138A, 138B may be configured as terminals and/or interconnect traces that may be routed appropriately.

In some implementations, the patterning of via apertures may include bottom layer anti-reflective coating (BARC) fill and etchback in the photolithography. As part of copper BEOL processing, the via apertures may be filled with copper (or other conductive material), annealed and polished (e.g., via CMP). In some implementations, a barrier or seed layer may be deposited, which may include a copper diffusion barrier layer comprising the same material (e.g., TaN) as the metallic barrier layers 128 of the header structures 125A, 125B. In similar fashion, the damascene formation of the metal interconnect traces 138A and 138B may include forming a TaN diffusion barrier layer. By way of illustration, reference number 136 in FIG. 1I refers to the via and interconnect trace diffusion barrier layers, where the via diffusion barrier layers 136 are in contact with the header diffusion barrier layers 128. Although the examples herein illustrate TaN-based implementations with respect to the header diffusion barrier layer 128 and the via diffusion barrier layer 136, the present disclosure is not limited thereto. In some additional and/or alternative examples, material compositions including Ta, Ta—Si—N, W, W—N, and W—Si—N may be used for forming the header diffusion barrier layer 128 and the via diffusion barrier layer 136 with respect to a TFR integration scheme.

In some arrangements, one or more inter-level vias may also be formed in the process of forming the conductive vias 134A, 134B with respect to the TFR header structures 125A and 125B. As illustrated in FIG. 1I, an inter-level via 142 may be formed that extends from a metal interconnect trace 140 coplanar with the metal interconnect traces 138A, 138B to a lower level metal interconnect trace, e.g., copper interconnect structure 118. Similar to the conductive vias 134A, 134B (also referred to as TFR header vias), the formation of inter-level vias 142 may include forming a diffusion barrier layer 137. In example arrangements herein, the via etch process may be configured such that differential selectivity of the etch with respect to the TaN barrier layers 128 relative to the dielectric layers 122, 126 may be utilized in preventing header punch-through during the formation of the header vias 134A and 134B while potentially longer inter-level vias 142 are also being formed.

FIG. 1J depicts a stage of the semiconductor device 100 where an etch stop layer 144 is formed, which may be used for facilitating the fabrication of additional or next level metal interconnect structures of a multilevel Cu interconnect scheme associated with the semiconductor device 100. In some examples, the etch stop layer 144 may have a thickness of about 30 nm to 80 nm and may comprise similar materials as the etch stop layer 112 described previously. Depending on application, one or more additional TFRs having the header structures similar to the header structures 125A and 125B may be fabricated at same or different levels of metallization, where the TFRs may be provided as part of a resistive ladder network, for example. Metal interconnect structures provided at corresponding levels, e.g., traces 138A and 138B, may be configured as a horizontal routing layer operable to provide access and/or connectivity with respect to the TFR resistive layer 124, where the horizontal routing layer may be routed to appropriate electrical nodes, e.g., bond pads, etc. (not shown in the Figures) associated with the semiconductor device 100. Although not specifically shown in FIG. 1J, the semiconductor device 100 may include a protective overcoat (PO) layer formed over a topmost metallization level. Depending on implementation, the PO layer may have a total thickness of several tens or hundreds of nanometers (nm) to several microns (μm) that may include one or more layers or sublayers of insulator materials such as, e.g., SiN, SiO, oxynitride, polyimide, etc., which may be deposited as part of a BEOL process flow.

Whereas the examples shown in FIGS. 1A-1J illustrate a TFR integration scheme within a two-level metal interconnect scheme, the metal interconnect structures 118 are broadly representative of lower level (e.g., (N−1)^{th} level) metal traces and the metal interconnect structures 138A/B and 140 are broadly representative of upper level (e.g., Nth level) metal traces of a multilevel interconnect that may be provided with a semiconductor device 100 in some additional and/or alternative examples. Further, although the examples herein illustrate a TFR arrangement where each terminal region includes a single electrical connection, the present disclosure is not limited thereto. In versions of some examples, a TFR's terminal region may be provided with multiple electrical connections, where each electrical connection may be effectuated by a corresponding via structure having a barrier metal layer as set forth in the foregoing description. Moreover, some example TFR arrangements may have one or more electrical connections formed at various locations along the resistive layer configured as “taps” for reference measurements or other purposes (e.g., variable resistor or rheostat applications), in addition to the electrical connections provided the respective terminal regions of a resistive layer, where the electrical connections may be connected to different nodes of an interconnect circuit.

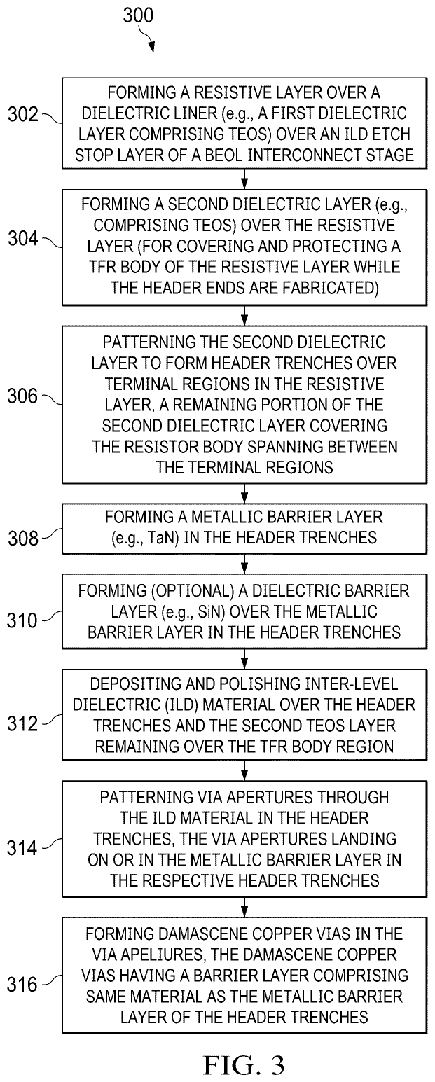

FIGS. 2 and 3 are flowcharts relating to IC fabrication methods according to some examples of the present disclosure. Method 200 shown in FIG. 2 may commence with forming a resistive layer over a semiconductor substrate (block 202), which may relate to some aspects of fabricating the resistive layer 124 described above. A first dielectric layer, e.g., dielectric layer 126, may be formed over the resistive layer, as set forth at block 204. At block 206, a metallic barrier layer may be formed contacting the resistive layer through an opening in the first dielectric layer, where the opening is formed over a header end of the resistive layer, which may relate to some aspects of header structure formation as set forth in FIGS. 1G-1 and 1G-2. At block 208, a conductive via may be formed that extends to the metallic barrier layer through a second dielectric layer over the resistive layer, where the metallic barrier layer is in contact with the conductive via and the resistive layer, which may relate to some aspects of fabrication of vias 134A and 134B as set forth in FIG. 1I. In versions of examples herein, the first and second dielectric layers may comprise a variety of dielectric materials depending on implementation, voltage levels of an application, etc.

Method 300 shown in FIG. 3 illustrates a representative process with additional details according to some examples. At block 302, a resistive layer may be formed over a dielectric liner (e.g., a first dielectric layer comprising TEOS) over an ILD etch stop layer of a BEOL interconnect stage, which may relate to some aspects shown in FIG. 1E. At block 304, a second dielectric layer (e.g., comprising TEOS) may be formed over the resistive layer, which may relate to some aspects shown in FIG. 1F. In some arrangements, a portion of the second dielectric layer remaining after header trench formation may be utilized for covering and protecting a resistive body portion of the resistive layer while the header ends are fabricated. At block 306, the second dielectric layer may be patterned to form header trenches or openings over terminal regions in the resistive layer, where the header trenches and the exposed terminal regions may be used for forming TFR headers and vias landing therein.

Relative to some aspects of FIGS. 1G-1 and 1G-2, a metallic barrier layer (e.g., TaN) may be formed in the header trenches as set forth at block 308. An optional dielectric layer (e.g., SiN) may be formed over the metallic barrier layer in the header trenches as set forth at block 310. Relative to some aspects of FIG. 1H, an ILD layer may be deposited over the header trenches and the second TEOS layer remaining over the TFR body region (block 312). At block 314, via apertures may be formed through the ILD material in the header trenches, the via apertures landing on the metaling barrier layer of the respective header trenches, which may relate to some aspects of FIG. 1I. At block 316, copper vias may be formed in the via apertures in a damascene process, where the copper vias may have a barrier layer comprising same material as the metallic barrier layer of the header trenches, which may relate to some aspects of FIG. 1I as noted above. Thereafter, metal interconnect traces may be formed at appropriate metal level using a damascene process for coupling to the vias, as set forth in FIG. 1J described above.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately over the other component, or that one component is immediately under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. An integrated circuit (IC), comprising:
a dielectric layer over a semiconductor substrate;
a resistive layer over the dielectric layer;
a metal interconnect trace over a header end of the resistive layer;
a via extending from the metallic interconnect trace toward the resistive layer; and
a metallic barrier layer between the via and the resistive layer, the metallic barrier layer contacting the via and the resistive layer.

2. The IC of claim 1, wherein the metallic barrier layer comprises a barrier material, and the barrier material surrounds the via and the metal interconnect trace.

3. The IC of claim 1, wherein the metal interconnect trace and the via are copper damascene structures.

4. The IC of claim 1, wherein the resistive layer comprises silicon chromium (SiCr).

5. The IC of claim 1, wherein the dielectric layer is a first dielectric layer, and further comprising a second dielectric layer over the first dielectric layer, wherein the via extends through the second dielectric layer and a third dielectric layer to the metallic barrier layer.

6. The IC of claim 1, wherein the metal interconnect trace is a first interconnect trace and the via is a first via, and further comprising:
a second interconnect trace coplanar with the first interconnect trace;
a third interconnect trace below the second interconnect trace; and
a second via connecting the second and third interconnect traces, the second via extending through the dielectric layer.

7. The IC of claim 6, wherein the first interconnect trace is a third metal level trace and the second interconnect trace is a second metal level trace.

8. The IC of claim 1, wherein the header end is a first header end, the metal interconnect trace is a first interconnect trace, the metallic barrier layer is a first metallic barrier layer, and the via is a first via, and further comprising:
a second metal interconnect trace coplanar with the first interconnect trace;
a second via extending from the second metal interconnect trace toward a second header end of the resistive layer; and
a second metallic barrier layer between the second via and the resistive layer.

9. The IC of claim 8, wherein the second metallic barrier layer comprises a barrier material, and the barrier material surrounds the second via and the second metal interconnect trace.

10. The IC of claim 9, wherein the barrier material comprises a material selected from the group consisting of TaN, Ta, Ta—Si—N, W, W—N, and W—Si—N.

11. A method of forming an integrated circuit, comprising:
forming a resistive layer over a semiconductor substrate;
forming a first dielectric layer over the resistive layer;
forming a metallic barrier layer contacting the resistive layer through an opening in the first dielectric layer; and
forming a conductive via that extends to the metallic barrier layer through a second dielectric layer over the resistive layer, the metallic barrier layer contacting the conductive via and the resistive layer.

12. The method of claim 11, wherein the metallic barrier layer comprises a barrier material, and the barrier material surrounds the conductive via.

13. The method of claim 12, wherein the barrier material comprises a material selected from the group consisting of TaN, Ta, Ta—Si—N, W, W—N, and W—Si—N.

14. The method of claim 11, wherein the resistive layer comprises silicon chromium (SiCr).

15. The method of claim 11, wherein the opening is formed over a header end of the resistive layer, and further comprising forming a dielectric barrier layer over the metallic barrier layer in the opening before forming the second dielectric layer.

16. The method of claim 15, wherein the dielectric barrier layer comprises silicon nitride.

17. The method of claim 11, wherein the conductive via is a first conductive via, and further comprising forming a second conductive via extending from an upper metal interconnect trace through the second dielectric layer and the first dielectric layer to a metal interconnect trace below the resistive layer.

18. The method of claim 17, wherein the first and second conductive vias and the metal interconnect traces are copper damascene structures.

19. The method of claim 11, wherein the first and second dielectric layers comprise material layers having an etch rate higher than an etch rate of the metallic barrier layer during via etch.

20. A method, comprising:
forming a first dielectric layer over a semiconductor substrate;
forming a resistive layer over the first dielectric layer;
forming a second dielectric layer over the resistive layer;
patterning the second dielectric layer to form header trenches over header regions of the resistive layer, a remaining portion of the second dielectric layer covering a resistor body spanning between the header regions of the resistive layer;
forming a metallic barrier layer in the header trenches;
depositing an inter-level dielectric (ILD) layer over the header trenches and the remaining portion of the second dielectric layer;
forming vias in or through the ILD layer, the vias each landing on the metal barrier layer in respective header trenches; and
forming metal interconnect traces over and in electrical contact with the vias, the metal interconnect traces and the vias surrounded by a same barrier material as the metallic barrier layer.
